(19) United States
(12) Patent Application Publication
(10) Pub. No.: US 2015/0137323 A1
(43) Pub. Date: May 21, 2015

(54) METHOD FOR FABRICATING THROUGH SILICON VIA STRUCTURE

(71) Applicant: UNITED MICROELECTRONICS CORP., Hsin-Chu City (TW)

(72) Inventors: ZHIBIAO ZHOU, Singapore (SG); Shao-Hui Wu, Singapore (SG); Chi-Fa Ku, Kaohsiung City (TW)

(73) Assignee: UNITED MICROELECTRONICS CORP., Hsin-Chu City (TW)

(21) Appl. No.: 14/080,798

(22) Filed: Nov. 15, 2013

(51) Int. Cl. H01L 21/768; H01L 23/48

(52) U.S. Cl. CPC H01L 21/76898; H01L 23/481
USPC 257/621; 438/524

(57) ABSTRACT

A method for fabricating through silicon via (TSV) structure is disclosed. The method includes the steps of: providing a substrate; forming a through-silicon via (TSV) in the substrate; depositing a liner in the TSV; removing the liner in a bottom of the TSV; and filling a first conductive layer in the TSV for forming a TSV structure.

### BACKGROUND OF THE INVENTION

1. Field of the Invention

The invention relates to a method for fabricating a through-silicon via (TSV) structure, and more particularly, to a method of removing the liner in the bottom of the TSV before filling conductive layer in the TSV for forming a TSV structure.

2. Description of the Prior Art

The through-silicon via technique is a novel semiconductor technique. The through-silicon via technique mainly servers to solve the problem of electrical interconnection between chips and belongs to a new 3D packing field. The through-silicon via technique produces products that meet the market trends of “light, thin, short and small” through the 3D stacking technique and also provides wafer-level packages utilized in micro electronic mechanic system (MEMS), and photoelectronics and electronic devices.

The through-silicon via technique drills holes in the wafer by etching or laser then fills the holes with conductive materials, such as copper, polysilicon or tungsten to form vias, i.e. conductive channels connecting inner regions and outer regions. The wafer or the dice is then thinned to be stacked or bonded together to form a 3D stack IC. By using this approach, the wire bonding procedure could be omitted. Using etching or laser to form conductive vias not only omits the wire bonding but also shrinks the occupied area on the circuit board and the volume for packing. The inner connection distance of the package created by using the through-silicon via technique, i.e. the thickness of the thinned wafer or the dice, is much shorter compared with the conventional stack package of wire bonding type. The performance of the 3D stack IC would therefore be much better in many ways, including faster transmission, and lower noise. The advantage of the shorter inner connection distance of the through-silicon via technique becomes much more pronounced in CPU, flash memory and memory card. As the 3D stack IC could be fabricated to equate the size of the dice, the utilization of through-silicon via technique becomes much more valuable in the portable electronic device industry.

The conventional approach for fabricating TSV structure however does not allow one to test for inline TSV resistance before full fabrication process is completed. That is, as the bottom of a TSV structure is typically isolated by an oxide liner, TSI daisy chain related parameters are not testable. Instead, test for inline TSV resistance under different voltage and frequency could only be carried out after backside redistribution layer (RDL) is completed, which at such point is usually too late for detecting inline issues and problems.

### SUMMARY OF THE INVENTION

It is therefore an objective of the present invention to provide a TSV structure and method for fabricating the same for resolving the aforementioned issues resulted from conventional approach.

According to a preferred embodiment of the present invention, a method for fabricating through silicon via (TSV) structure is disclosed. The method includes the steps of: providing a substrate; forming a through-silicon via (TSV) in the substrate; depositing a liner in the TSV; removing the liner in a bottom of the TSV; and filling a first conductive layer in the TSV for forming a TSV structure.

According to another aspect of the present invention, a TSV structure is disclosed. The TSV structure includes: a through silicon via (TSV) in a substrate; a first conductive layer in the TSV, wherein the bottom of the first conductive layer contacts the substrate; and a liner between the first conductive layer and the TSV.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-8 illustrate a method for fabricating a TSV structure according to a preferred embodiment of the present invention.

FIGS. 9-13 illustrate a metal first process for fabricating TSV structure according to an embodiment of the present invention.

FIGS. 14-18 illustrate a via first process for fabricating TSV structure according to an embodiment of the present invention.

### DETAILED DESCRIPTION

Referring to FIGS. 1-8, FIGS. 1-8 illustrate a method for fabricating a TSV structure according to a preferred embodiment of the present invention. As shown in FIG. 1, a substrate 12 composed of monocrystalline silicon, gallium arsenide (GaAs), silicon on insulator (SOI) layer, epitaxial layer, or other known semiconductor material is provided.

It should be noted that as the TSV structure fabricated in this embodiment is preferably utilized as a through silicon interposer (TSI), no active device is formed on the substrate 12. However, at least a semiconductor device including metal-oxide semiconductor (MOS) transistors such as PMOS transistors, NMOS transistors, or complimentary metal-oxide semiconductor (CMOS) transistors could also be selectively formed on top of the substrate depending on the demand of the product, which is also within the scope of the present invention.

Next, a dielectric layer 14 is deposited on the substrate. The dielectric layer 14 could include an oxide layer consisting of silicon oxynitride (SiON), silicon oxide (SiO), or tetraethylorthosilicate (TEOS), in which the layer could be formed through a thermal oxidation process or a deposition process such as a chemical vapor deposition (CVD) process or an atomic layer deposition (ALD) process, but not limited thereto. In addition, the dielectric layer 14 may also be a single layered structure or a multi-layered structure, which are all within the scope of the present invention.

Next, a photo-etching process could be carried out to form at least a TSV 16 in the dielectric layer and the substrate. It should be noted that even though two TSVs 16 are revealed in this embodiment, the quantity of the TSV 16 is not limited to two, but could be any quantity more than one depending on the demand of the product.

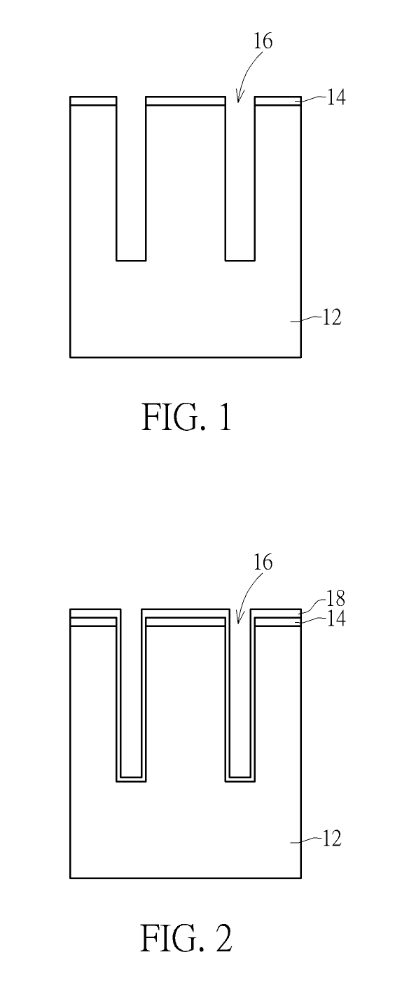

Next, as shown in FIG. 2, a liner 18 is deposited in the TSV 16. Preferably, the liner 18 is deposited on the dielectric layer 14, sidewalls of the TSV 16, and bottom of the TSV 16, in which the liner 18 could be composed of oxides or nitrides, and could also be a single or composite layer.

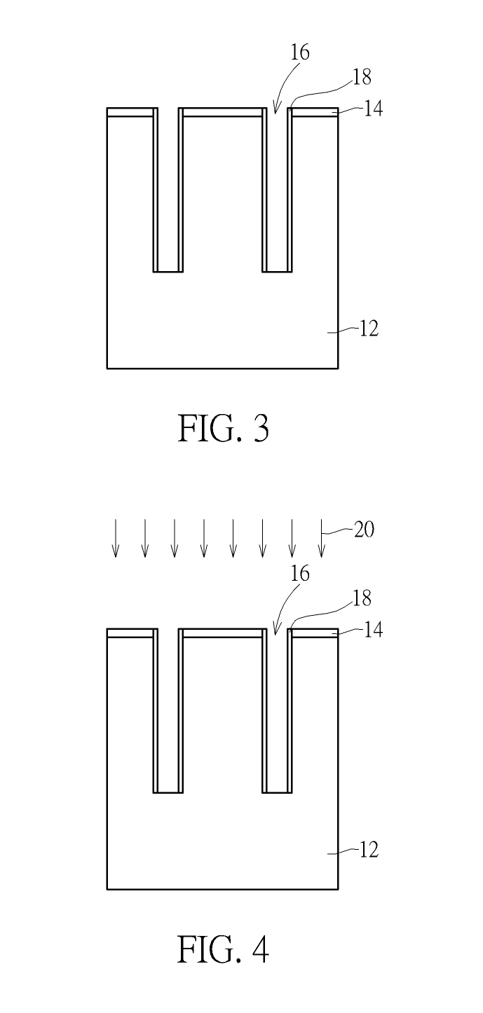

As shown in FIG. 3, an etching back process is performed to partially remove the liner 18 in the bottom of the TSV 16 so that at least a portion of the substrate 12 is exposed. According to a preferred embodiment of the present invention, the etching back process includes a dry etching process.

As shown in FIG. 4, a selective ion implantation process 20 could be conducted to implant dopants into the substrate and an anneal process could be performed thereafter for diffusing the implanted dopants. It should be noted that even though the ion implantation process 20 is preferably conducted from the front side of the substrate 12 as revealed in the figure, the ion implantation process 20 could also be carried out from a backside of the substrate 12, which is also within the scope of the present invention. Moreover, depending on the nature of the device being fabricated, the implanted dopants could include p-type and n-type dopants.

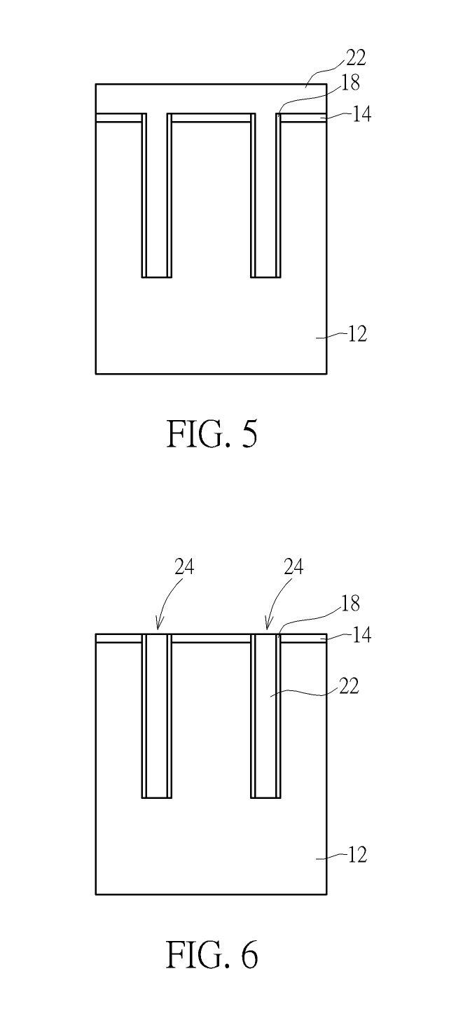

As shown in FIG. 5, a chemical vapor deposition (CVD) is conducted to form a selective barrier layer (not shown) and a selective seed layer (not shown) on a surface of the dielectric layer 14 and the liner 18, and a conductive layer 22 composed of copper is electroplated on the seed layer and in the TSV 16. Preferably, the conductive layer 22 is formed on the dielectric layer 14 and filling the entire TSV 16 and as the bottom of the TSV 16 is exposed, the conductive layer 22 preferably contacts the substrate 12 directly.

The barrier layer is preferably selected from a group consisting of Ta, TaN, Ti, and TiN, which could be used to prevent copper ions of the conductive layer 22 from migrating to the surrounding liner 18. The seed layer is preferably used to adhere copper ions of the conductive layer 22 onto the liner for facilitating the copper electroplating process thereafter. In addition to the materials listed above, the material used for the conductive layer 22, the barrier layer, and the seed layer could be adjusted according to the demand of the product, which is all within the scope of the present invention.

According to an embodiment of the present invention, a salicide process could also be conducted before the formation of the conductive layer 22 by slightly modifying the steps for forming the barrier/seed layer. For instance, a metal layer selected from a group consisting of cobalt, titanium, nickel, platinum, palladium, and molybdenum could be deposited into the TSV 16 during the deposition of the barrier/seed layer, and a rapid thermal anneal process could be accompanied thereafter to form a silicide layer in the TSV 16. After removing un-reacted metal, the aforementioned conductive layer 22 is filled into the TSV 16 and in this instance, the conductive layer 22 would be contacting the silicide layer directly instead of the substrate 12.

After the conductive layer 22 is electroplated into the TSV 16, as shown in FIG. 6, a planarizing process, such as a chemical mechanical polishing (CMP) process is conducted to partially remove the conductive layer 22 on top of the dielectric layer 14 so that the surface of the dielectric layer 14 is even with the surface of the conductive layer 22 embedded within the TSV 16. This forms a plurality of TSV structures 24 in the substrate 12.

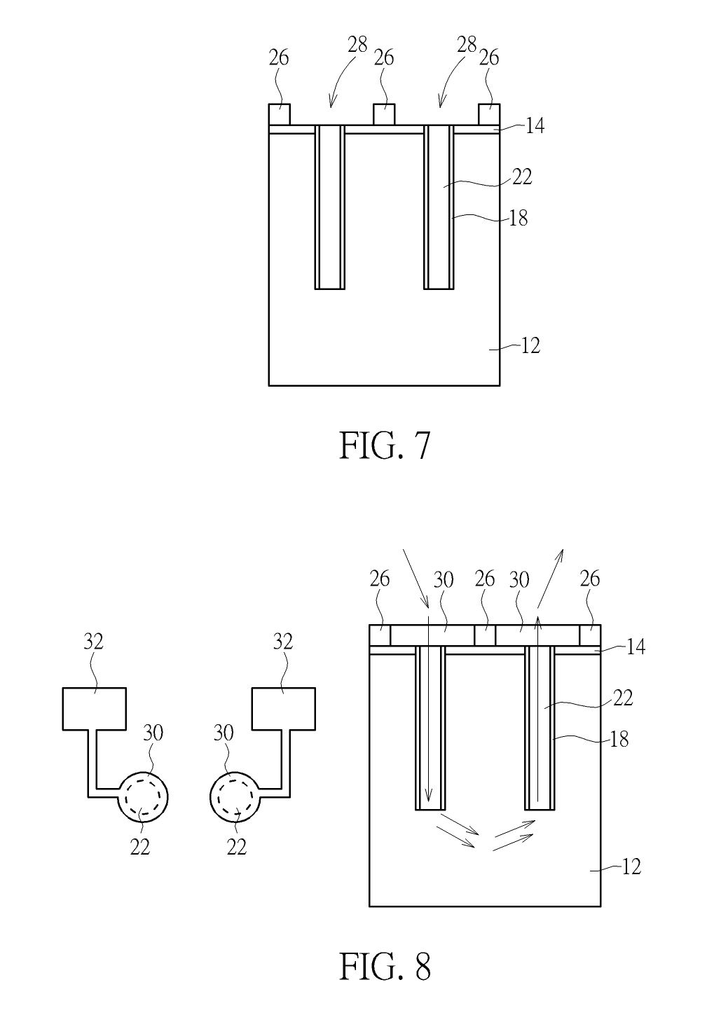

Next, as shown in FIG. 7, an inter-metal dielectric (IMD) layer 26 is formed on the dielectric layer 14 and the TSV structures 24, and a patterning process, such as a photo-etching process is conducted to form a plurality of openings 28 in the IMD layer 26 for exposing the surface of each TSV structure 24.

As shown in FIG. 8, another selective barrier/seed layer (not shown) and a conductive layer 30 are formed in the openings 28 of the IMD layer 26 and on top of the IMD layer 26, and a planarizing process, such as a CMP process is conducted thereafter to partially remove the conductive layer 30 so that the top surface of the conductive layer 30 deposited into the openings 28 is even with the top surface of the IMD layer 26. This completes the formation of a plurality of TSV structures along with metal one structures according to a preferred embodiment of the present invention.

After the integrated structure of TSVs and metal one structures are completed, each of the conductive layers 30 embedded in the IMD layer 26 could be further connected to a pad 32 individually and inline monitor could be tested accordingly. For instance, as each of the TSVs contacts the substrate directly, it would be desirable to use the TSV pairs as input and output and probe the TSV pair in the arrow direction shown in FIG. 8 to check for single pair and accumulated pair resistances and compare with baseline performance to determine the health level of the overall process by using the substrate 12 as a connection bridge therebetween. Ultimately, inline monitor for TSV resistance under different force voltage and frequency could be thoroughly tested and studied even before backside RDL process is completed.

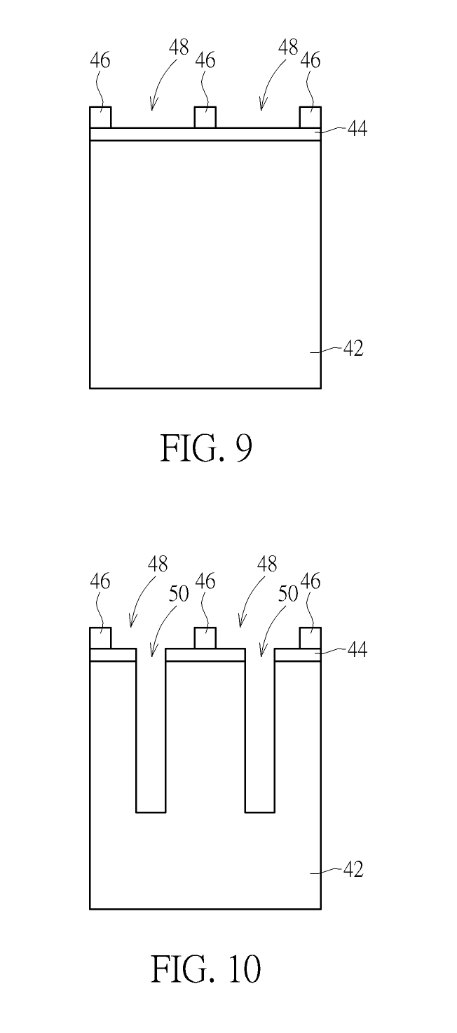

Referring to FIGS. 9-13, FIGS. 9-13 illustrate a metal first process for fabricating TSV structure according to an embodiment of the present invention. As shown in FIG. 9, a substrate 42 is provided, and a dielectric layer 44 is formed on the substrate 42. After the dielectric layer 44 is formed, a IMD layer 46 is formed on the dielectric layer 44, and a photo-etching process is conducted to pattern the IMD layer 46 for forming a plurality of openings 48 in the IMD layer 46. Preferably, the dielectric layer 44 and the IMD layer 46 may be consisted of same or different material and if the two layers 44 and 46 are consisted of same material, a stop layer (not shown) may be formed between the two layers 44 and 46 before the photo-etching process is carried out. As this design is well known to those skilled in the art, the details of which are omitted herein for the sake of brevity.

Next, as shown in FIG. 10, another photo-etching process is performed to form at least a TSV 50 in the IMD layer 46, dielectric layer 44 and the substrate 42. Similar to the aforementioned embodiment, even though two TSVs 50 are revealed in this embodiment, the quantity of the TSV 50 is not limited to two, but could be any quantity more than one depending on the demand of the product.

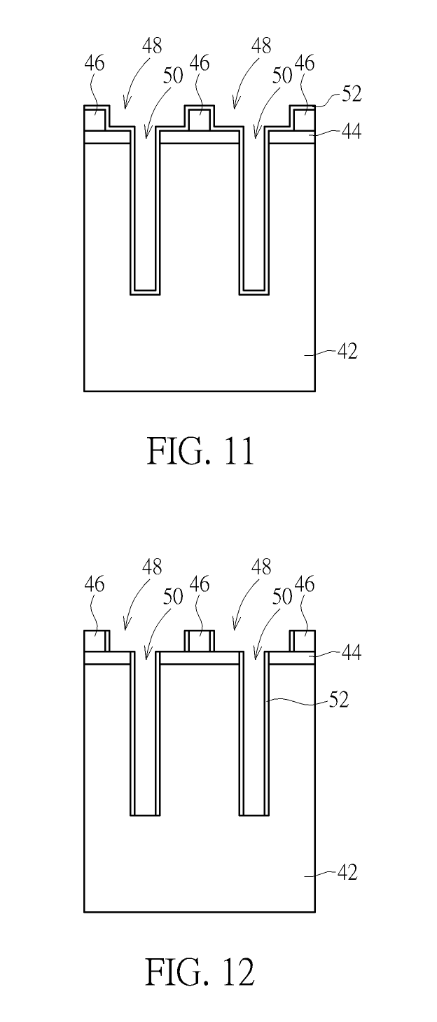

Next, as shown in FIG. 11, a liner 52 is deposited in the TSV 50. Preferably, the liner 52 is deposited on the top surface of the IMD layer 46, sidewalls of the IMD layer 46, sidewalls of the dielectric layer 44, sidewalls of the TSV 50, and bottom of the TSV 50, in which the liner 52 could be composed of oxides or nitrides, and could also be a single or composite layered structure.

Next, as shown in FIG. 12, an etching back process is performed to partially remove the liner 52 in the bottom of the TSV 50 and on top of the IMD layer 46 so that at least a portion of the substrate 42 is exposed.

Similar to the aforementioned embodiment, a selective ion implantation process and/or a selective salicide process could be conducted prior to fill a conductive layer into the TSV 50. Preferably, the ion implantation is conducted from the front side of the substrate 42, but could also be carried out from a backside of the substrate 42, which are also within the scope of the present invention. As the implementation of ion implantation process and salicide process has been fully disclosed in the aforementioned embodiment, the details of which are not further explained herein for the sake of brevity.

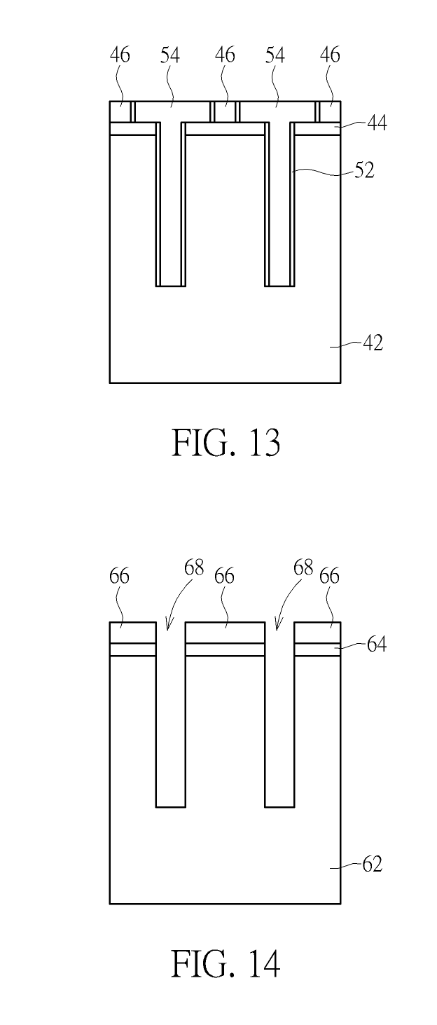

Next, as shown in FIG. 13, a selective barrier layer (not shown) and a selective seed layer (not shown) could be deposited on the IMD layer 46 and the liner 52, and a conductive layer 54 composed of copper is formed to fill the TSV 50. Preferably, the conductive layer 54 is electroplated to fill both the openings of the IMD layer 46 and the entire TSV 50, and as the bottom of the TSV 50 is exposed, the conductive layer 54 preferably contacts the substrate 42 directly. After the conductive layer 54 is fully deposited into the TSV 50, a CMP process is conducted thereafter to partially remove the conductive layer 54 so that the surface of the IMD layer 46 is even with the top surface of the conductive layer 54. This completes the fabrication of a plurality of TSV structures through metal first process according to an embodiment of the present invention.

Referring to FIGS. 14-18, FIGS. 14-18 illustrate a via first process for fabricating TSV structure according to an embodiment of the present invention. As shown in FIG. 14, a substrate 62 is first provided, and a dielectric layer 64 and a IMD layer 66 is formed on the substrate 62 thereafter. Next, a photo-etching process is performed to form at least a TSV 68 in the IMD layer 66, the dielectric layer 64, and the substrate 62. Similar to the aforementioned embodiments, even though only two TSVs 68 are revealed in this embodiment, the quantity of the TSV 68 is not limited to two, but could be any quantity more than one depending on the demand of the product. Moreover, the dielectric layer 64 and the IMD layer 66 may be consisted of same or different material and if the two layers 64 and 66 are made of same material, a stop layer (not shown) may be formed between the two layers 64 and 66 before the TSVs 68 are formed. As this design is well known to those skilled in the art, the details of which are omitted herein for the sake of brevity.

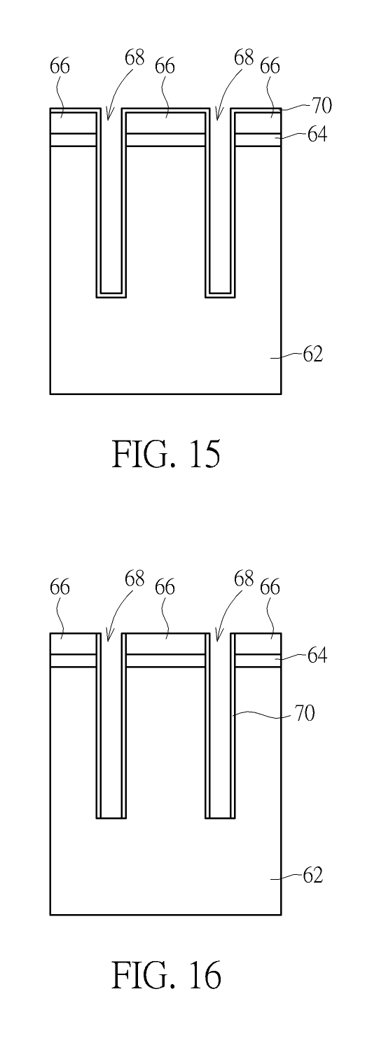

Next, as shown in FIG. 15, a liner 70 is deposited in the TSV 68. Preferably, the liner 70 is deposited on the top surface of the IMD layer 66, sidewalls of the IMD layer 66, sidewalls of the dielectric layer 64, sidewalls of the TSV 68, and bottom of the TSV 68, in which the liner 70 could be composed of oxides or nitrides, and could also be a single layer or a composite layer structure.

Next, as shown in FIG. 16, an etching back process is performed to partially remove the liner 70 in the bottom of the TSV 68 and on top of the IMD layer 66 so that at least a portion of the substrate 62 is exposed.

Similar to the aforementioned embodiments, a selective ion implantation process and/or a selective salicide process could be conducted prior to fill a conductive layer into the TSV 68. Preferably, the ion implantation is conducted from the front side of the substrate 62, but could also be carried out from a backside of the substrate 62, which are within the scope of the present invention. As the implementation of ion implantation process and salicide process have been disclosed in the aforementioned embodiment, the details of which are not further explained herein for the sake of brevity.

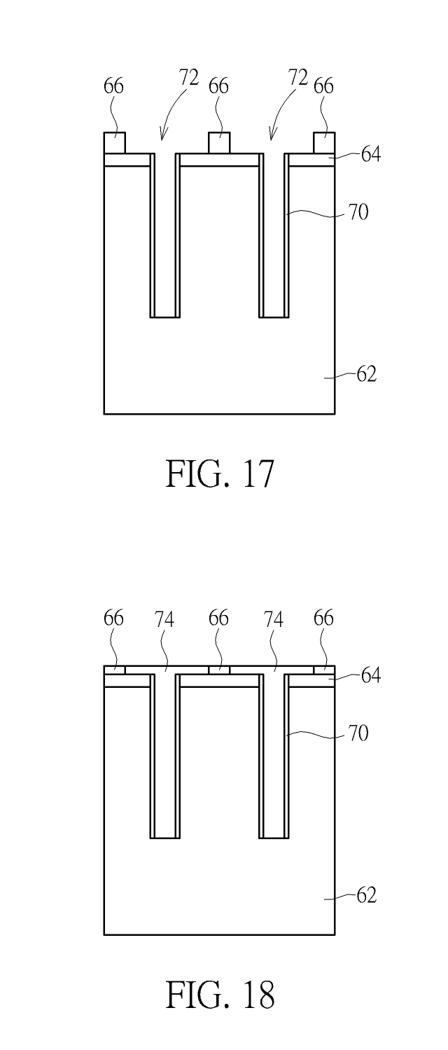

Next, as shown in FIG. 17, a photo-etching process is performed to pattern the IMD layer 66 for forming a plurality of openings 72 in the IMD layer 66. It should be noted that the photo-etching process preferably removes part of the liner 70 from the sidewalls of the IMD layer 66 as the openings 72 are formed.

Next, as shown in FIG. 18, a selective barrier layer (not shown) and a selective seed layer (not shown) could be deposited on the IMD layer 66 and the liner 70, and a conductive layer 74 composed of copper is formed to fill the TSV 68. Preferably, the conductive layer 74 is electroplated to fill both the openings 72 in the IMD layer 66 and the entire TSV 68, and as the bottom of the TSV 68 is exposed, the conductive layer 74 preferably contacts the substrate 62 directly. A CMP process is conducted thereafter to partially remove the conductive layer 74 so that the surface of the IMD layer 66 is even with the top surface of the conductive layer 74. This completes the fabrication of a plurality of TSV structures through via first process according to an embodiment of the present invention.

Overall, the present invention preferably deposits a liner in a TSV and the removes the liner from the bottom of the TSV to expose the bottom of the TSV before conductive material is deposited to fill the TSV. By doing so, the conductive material, preferably copper, being filled into the TSV thereafter could contact the substrate directly so that TSV early test could be performed to determine process or defect issue at a much earlier stage of the fabrication cycle.

Those skilled in the art will readily observe that numerous modifications and alterations of the device and method may be made while retaining the teachings of the invention. Accordingly, the above disclosure should be construed as limited only by the metes and bounds of the appended claims.

1. A method for fabricating through silicon via (TSV) structure, comprising:
providing a substrate;
forming a through-silicon via (TSV) in the substrate;
depositing a liner in the TSV;
removing the liner in a bottom of the TSV; and
filling a first conductive layer in the TSV for forming a TSV structure.

2. The method for fabricating TSV structure of claim 1, further comprising:
forming a dielectric layer on the substrate;
forming the TSV in the dielectric layer and the substrate;
depositing the liner on the dielectric layer, sidewalls of the TSV, and bottom of the TSV;
etching back the liner in the bottom of the TSV;
depositing the first conductive layer on the dielectric layer and in the TSV such that the first conductive layer contacts the substrate; and
planarizing the first conductive layer on the dielectric layer for forming the TSV structure.

3. The method for fabricating TSV structure of claim 2, further comprising:
forming an inter-metal dielectric layer on the dielectric layer and the TSV structure;
forming an opening in the inter-metal dielectric layer for exposing the TSV structure;
forming a second conductive layer in the opening; and
planarizing the second conductive layer.

4. The method for fabricating TSV structure of claim 3, wherein the first conductive layer and the second conductive layer comprise copper.

5. The method for fabricating TSV structure of claim 1, further comprising:
forming a dielectric layer on the substrate;
forming an inter-metal dielectric layer on the dielectric layer;
forming an opening in the inter-metal dielectric layer;
forming the TSV in the dielectric layer and the substrate;
depositing the liner on the inter-metal dielectric layer, the dielectric layer, and in the TSV;
etching back the liner in the bottom of the TSV and on top of the inter-metal dielectric layer;
filling the first conductive layer in the TSV and the opening; and
planarizing the first conductive layer for forming the TSV structure.

6. The method for fabricating TSV structure of claim 1, further comprising:
forming a dielectric layer on the substrate;
forming an inter-metal dielectric layer on the dielectric layer;
forming the TSV in the inter-metal dielectric layer, the dielectric layer, and the substrate;
depositing the liner on the inter-metal dielectric layer and in the TSV;
etching back the liner in the bottom of the TSV and on top of the inter-metal dielectric layer;
forming an opening in the inter-metal dielectric layer;
filling the first conductive layer in the TSV and the opening; and
planarizing the first conductive layer for forming the TSV structure.

7. The method for fabricating TSV structure of claim 1, further comprising:
performing an ion implantation process for implanting dopants into the substrate before filling the first conductive layer; and
performing an annealing process.

8. The method for fabricating TSV structure of claim 7, further comprising performing the ion implantation process from a backside of the substrate.

9. The method for fabricating TSV structure of claim 7, wherein the dopants comprise p-type and n-type dopants.

10. The method for fabricating TSV structure of claim 1, wherein the liner comprises oxide.

11. The method for fabricating TSV structure of claim 1, further comprising:
performing a salicide process for forming a silicide layer in the bottom of the TSV; and
filling the first conductive layer in the TSV and on the silicide layer.

12. The method for fabricating TSV structure of claim 1, further comprising forming at least a semiconductor device on the substrate before forming the TSV.

13. The method for fabricating TSV structure of claim 12, wherein the semiconductor device comprises complimentary metal-oxide semiconductor (CMOS) transistor.

14. A through silicon via structure, comprising:
a through silicon via (TSV) in a substrate;
a first conductive layer in the TSV, wherein the bottom of the first conductive layer contacts the substrate; and
a liner between the first conductive layer and the TSV.

15. The through silicon via structure of claim 14, further comprising:
a patterned inter-metal dielectric layer on the dielectric layer, wherein the patterned inter-metal dielectric layer comprises an opening exposing the first conductive layer; and
a second conductive layer in the opening.

16. The through silicon via structure of claim 15, wherein the first conductive layer and the second conductive layer comprise copper.

17. The through silicon via structure of claim 14, wherein the liner comprises oxide.

18. The through silicon via structure of claim 14, further comprising a silicide layer between the substrate and the first conductive layer.

19. The through silicon via structure of claim 14, further comprising at least a semiconductor device on the substrate.

20. The through silicon via structure of claim 19, wherein the semiconductor device comprises complimentary metal-oxide semiconductor (CMOS) transistor.
